(19) United States
(12) Patent Application Publication
(10) Pub. No.: US 2004/0042546 A1
(43) Pub. Date: Mar. 4, 2004

(54) Single carrier receiver with an equalizer for improving equalization quality and equalization method thereof

(75) Inventors: Dong-Seong Han, Daegu-City (KR); Hae-Sock Oh, Daegu-City (KR); Ju-Yeun Kim, Daegu-City (KR); Jung-Jin Kim, Daegu-City (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-City (KR)

(21) Appl. No.: 10/426,813

(22) Filed: May 1, 2003

(30) Foreign Application Priority Data
Sep. 2, 2002 (KR) 2002-52626

(51) Int. Cl. H03K 5/159; H03H 7/30; H03H 7/40

(52) U.S. Cl. 375/233

(57) ABSTRACT

An equalizer of a single carrier receiver and method thereof include a pre-ghost detection unit, a delay unit, an FF unit, and an FB unit. The pre-ghost detection unit detects one ghost from ghosts having levels higher than a predetermined threshold and detects a time delay of the detected ghost with respect to a main ghost. The delay unit delays an input field synchronization signal for the time delay and outputs a delay signal indicative thereof. The FF unit receives a pre-ghost to filter ghosts received before the detected ghost. The FB unit receives the delayed field synchronization signal to filter the ghosts received after the detected ghost.

### CROSS-REFERENCE TO RELATED APPLICATIONS

This application claims the priority of Korean Patent Application No. 2002-52626, filed Sep. 2, 2003 in the Korean Intellectual Property Office, the disclosure of which is incorporated herein by reference.

### BACKGROUND OF THE INVENTION

1. Field of the Invention

The present invention relates to a digital signal equalizer employing a single carrier mode, and more particularly, to an equalizer capable of improving equalization quality.

2. Description of the Related Art

FIG. 1 is a schematic block diagram of a conventional single carrier receiver capable of receiving a broadcasting signal transmitted in a general single carrier mode.

The single carrier receiver includes an RF (Radio Frequency) unit 10, an ADC (Analog to Digital Converter) 20, a synchronizer 30, an equalizer 40, a decoder 50 and a field synchronization signal generator 60. The RF unit 10 tunes a VSB broadcasting signal which is received from an antenna 11 from a VSB (Vestigial SideBand) transmitter and converts a tuned band of the VSB broadcasting signal to a baseband signal. The ADC 20 converts the baseband signal in an analog format to a digital signal by a digital sampling process. The synchronizer 30 compensates frequency, phase, and timing offsets for the digital input signal from the ADC 20. The equalizer 40 compensates a channel distortion on a transmission channel of a digital signal of the VSB broadcasting signal with offsets compensated as described below. The field synchronization signal generator 60 generates a field synchronization signal, which is a reference signal agreed between a transmitter and a receiver, thereby providing the generated field synchronizing signal to the equalizer 40. The field synchronization signal from the field synchronization signal generator 60 is provided to the field equalizer 40 to compensate the channel distortion. The decoder 50 decodes data from the digital signal of the VSB broadcasting signal equalized by the equalizer 40.

FIG. 2 is a block diagram of the equalizer 40 of FIG. 1, which may be a DFE (Decision Feedback Equalizer). FIG. 2 illustrates a training mode, that is, an operation mode in which the DFE equalizes a pre-ghost received based on a reference signal.

The DFE 40 includes an FF (Feed Forward) unit 41, an FB (Feed Back) unit 42, a first adder 43, a main ghost detector 45, a delay unit 46 and a second adder 47.

The FF unit 41, which is an FIR (Finite Impulse Response) type filter, filters pre-ghosts received before a main-ghost, which is a signal of a highest amplitude level from multipath signals. (Hereinafter ‘amplitude level’ is called ‘level’)

The FB unit 42, which is an IIR (Infinite Impulse Response) type filter, filters post-ghosts received after the main-ghost.

The first adder 43 adds output signals from the FF unit 41 and the FB unit 42, and a resulting signal is output from the DFE 40.

The main ghost detector 45 calculates a correlation value using a correlation between the pre-ghost received and a field synchronization signal generated in a field synchronization signal generator (not shown) of the receiver and cumulates correlation values to detect a time delay, which is a position of the main-ghost with respect to a time axis.

The delay unit 46 delays the field synchronization signal for a predetermined time, i.e., the time delay of the main-ghost, to output the delayed signal to the FB unit 42. The pre-ghosts and the post-ghosts respectively received before and after the main-ghost of highest level among multipath signals are filtered.

The second adder 47 calculates an equalization error by adding an output signal from the first adder 43 and the field synchronization signal delayed for the predetermined delay time by the delay unit 46. By using the equalization error, coefficients of the FF unit 41 and the FB unit 42 are updated to filter the multipath.

As described above, the FF unit 41 of the FIR type filters pre-ghosts received before the main-ghost and the FB unit 42 of the IIR type filters post-ghosts received after the main-ghost.

FIGS. 3A and 3B illustrate features of operations of the FIR filter 41 and the FB unit 42 of FIG. 2. A description, hereinafter, will be given in accordance with a process to filter the pre-ghosts and the post-ghosts received before or after the main-ghost having the highest level from the received multipath signals, which is detected as a main signal, through the FIR filter 41 and the FB unit 42 with reference to FIGS. 3A and 3B. A delay profile for a pre-ghost received is shown in FIG. 3A.

The FF unit 41 has coefficients corresponding to the FIR filter, which are converged in a way as to gradually reduce levels of the pre-ghosts. The FB unit 42 has coefficients corresponding to the IIR filter, which are converged by adopting inverse numbers of levels of the post-ghosts to remove the post-ghosts. Namely, as shown in FIG. 3B, the FIR filter gradually reduces the level of each ghost at time intervals of the delay time of the main-ghost to filter each ghost, while the IIR filter adopts a negative number of the level of each ghost to filter each ghost.

As shown in 3B, the FIR filter needs a large number of filter taps to filter a ghost having a high level. This causes deterioration of a quality of the equalizer for equalizing the high level ghost.

### SUMMARY OF THE INVENTION

Various aspects and advantages of the invention will be set forth in part in the description that follows and, in part, will be obvious from the description, or may be learned by practice of the invention.

Accordingly, an aspect of the present invention is to solve the foregoing problems by providing an equalizer of a single carrier receiver equalizing ghosts by using one ghost among ghosts, which have a higher level than a predetermined threshold and which is received as a main signal before the ghost having a highest level.

The foregoing and/or other aspects and advantages are realized by providing an equalizer for a single carrier receiver, including: a pre-ghost detection unit detecting one ghost from ghosts having levels higher than a predetermined threshold and detecting a time delay of the detected ghost with respect to a main ghost; a delay unit delaying an input field synchronization signal for the time delay and outputting a delay signal indicative thereof; an FF unit receiving a pre-ghost to filter ghosts received before the detected ghost; and an FB unit receiving the delayed field synchronization signal to filter the ghosts received after the detected ghost. The equalizer further includes a first adding unit adding output signals from the FF unit and the FB unit and outputting an output signal indicative thereof; and a second adding unit calculating an equalization error by using the output signal from the first adding unit and the delay signal or the delayed field synchronization signal from the delay unit, wherein the FF unit and FB unit filter the ghosts received before and after the detected ghost, respectively, according to the equalization error.

According to an aspect of the present invention, the pre-ghost detection unit includes: a correlation value calculation unit calculating a correlation value between the pre-ghost received and the field synchronization signal; a multipath estimation unit cumulating correlation values calculated using a plurality of field synchronization signals to estimate a multipath of the pre-ghost received; and a pre-ghost decision unit detecting the ghost from the ghosts having the levels higher than the predetermined threshold and detecting the time delay of the detected ghost.

According to another aspect of the invention, an equalization method of a linear equalizer for a single carrier receiver, the equalization method includes detecting one ghost from ghosts having levels higher than a predetermined threshold as a pre-ghost and detecting a time delay of the detected pre-ghost with respect to a main ghost; delaying an input field synchronization signal for the time delay; and filtering the ghosts received before and after the detected ghost. The equalization method further includes calculating an equalization error using the delayed field synchronization signal, wherein the filtering of the ghosts filters the ghosts received before and after the detected ghost according to the equalization error.

According to an aspect of the present invention, the pre-ghost detecting includes: calculating a correlation value between a pre-ghost received indicative of the ghosts received before the detected ghost and the field synchronization signal; estimating a multipath of the pre-ghost received by cumulating correlation values calculated using a plurality of field synchronization signals; and detecting the ghost from the ghosts having the levels higher than the predetermined threshold and detecting the time delay of the detected ghost.

According to another aspect of the invention, an equalizer for a single carrier receiver, includes: a pre-ghost detection unit detecting one ghost from ghosts having levels higher than a predetermined threshold and detecting a time delay of the detected ghost with respect to a main ghost; a field synchronization signal generation unit generating a first field synchronization signal delayed for the time delay; an FF unit receiving a pre-ghost to filter ghosts received before the detected ghost; and an FB unit receiving the delayed first field synchronization signal to filter the ghosts received after the detected ghost.

According to another aspect of the invention, an equalization method of a linear equalizer for a single carrier receiver, the equalization method includes: detecting one ghost from ghosts having levels higher than a predetermined threshold as a pre-ghost and detecting a time delay of the detected pre-ghost with respect to a main ghost; generating a first field synchronization signal delayed for the time delay; and filtering the ghosts received before and after the detected ghost.

According to an aspect of the present invention, there is provided an equalizer of a single carrier receiver, including: an FF (Feed Forward) unit filtering pre-ghosts received before a main-ghost; an FB (Feed Back) unit filtering post-ghosts received after the main-ghost; a first adder adding the filtered pre-ghosts and post-ghosts and outputting a resulting signal indicative thereof; a pre-ghost detector detecting one ghost from ghosts having levels higher than a predetermined threshold from the pre-ghosts received before the main-ghost, and detecting a time delay of the detected ghost; a delay unit delaying a field synchronization signal for the detected time delay and outputting the field synchronization signal to the FB unit; and a second adder calculating an equalization error by adding the resulting signal from the first adder and the delayed field synchronization signal, and using the equalization error to update coefficients of the FF unit and the FB unit.

According to an aspect of the present invention, there is provided an equalization method of a single carrier receiver, including: filtering pre-ghosts received before a main-ghost; filtering post-ghosts received after the main-ghost; adding the filtered pre-ghosts and post-ghosts and outputting a resulting signal indicative thereof; detecting one ghost from ghosts having levels higher than a predetermined threshold from the pre-ghosts received before the main-ghost; detecting a time delay of the detected ghost; delaying a field synchronization signal for the detected time delay of the detected ghost; and calculating an equalization error by adding the resulting signal and the delayed field synchronization signal.

According to an aspect of the present invention, there is provided an equalization method of a single carrier receiver, including: detecting one ghost from ghosts having higher levels than a predetermined threshold by applying the predetermined threshold to a pre-ghost received before the ghost having the highest level; detecting a time delay of the detected ghost; delaying an input field synchronization signal for the time delay; and filtering the ghosts received before and after the detected ghost.

Additional advantages, aspects, and features of the invention will be set forth in part in the description which follows and in part will become apparent to those having ordinary skill in the art upon examination of the following or may be learned from practice of the invention. The aspects and advantages of the invention may be realized and attained as particularly pointed out in the appended claims.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic block diagram of a VSB receiver;

FIG. 2 is a block diagram of a decision feedback equalizer of the VSB receiver in FIG. 1;

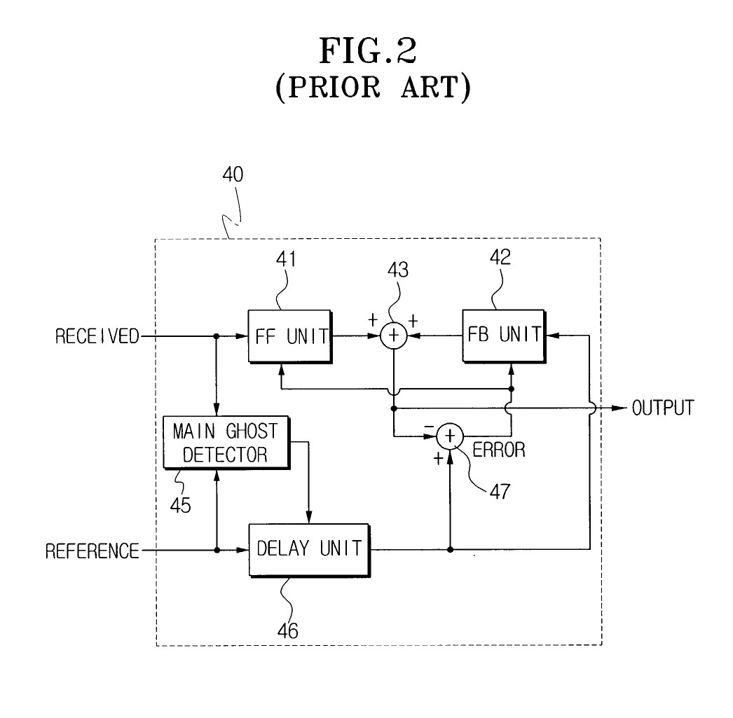

FIGS. 3A and 3B illustrate operations of an FIR filter and an FB unit of FIG. 2;

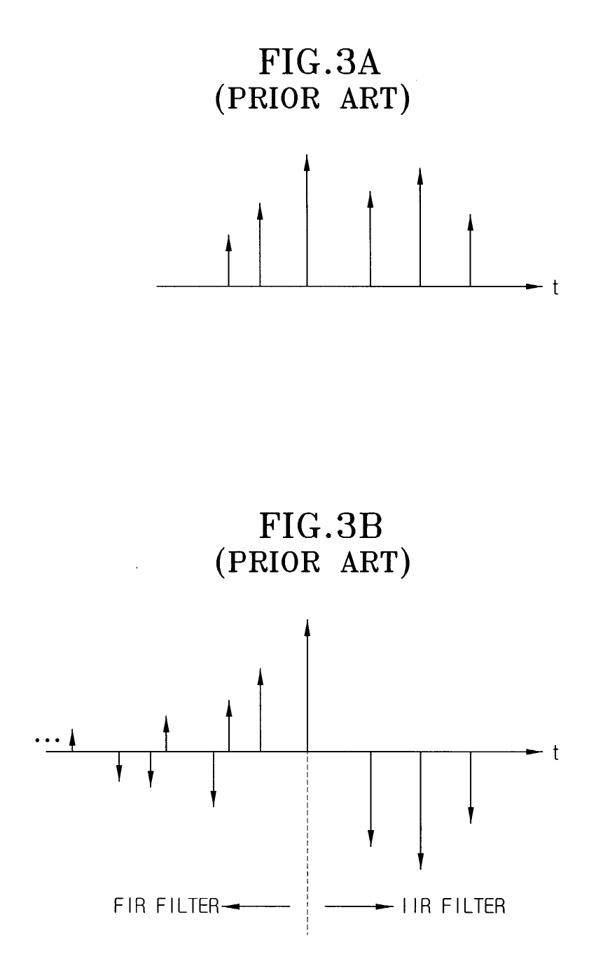

FIG. 4 is a block diagram of a decision feedback equalizer, in accordance with an aspect of the present invention;

FIG. 5 is a detailed block diagram of a pre-ghost detector of FIG. 4;

FIGS. 6A to 6C are diagrams to illustrate an operation of the pre-ghost detector of FIG. 5;

FIG. 7 is a flow chart illustrating an equalizing method of the decision feedback equalizer of FIG. 4;

FIG. 8 is a detailed flow chart illustrating detecting a delay time of a pre-ghost;

FIG. 9 is a block diagram of the decision feedback equalizer, in accordance with another aspect of the present invention; and

FIG. 10 is a flow chart illustrating the equalizing method of the decision feedback equalizer of FIG. 9.

### DETAILED DESCRIPTION OF PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

The following detailed description will present a VSB receiver with an equalizer to improve an equalization quality and an equalization method thereof, according to an aspect of the invention in reference to the accompanying drawings.

There are two operation modes of an equalizer, in accordance with an aspect of the present invention: a first operation mode is a blind mode in that an equalization of the equalizer is performed using a pre-ghost received and a second operation mode is a training mode in that the equalization of the equalizer is performed using a field synchronization signal, that is, a synchronization information signal between a transmitter and a receiver.

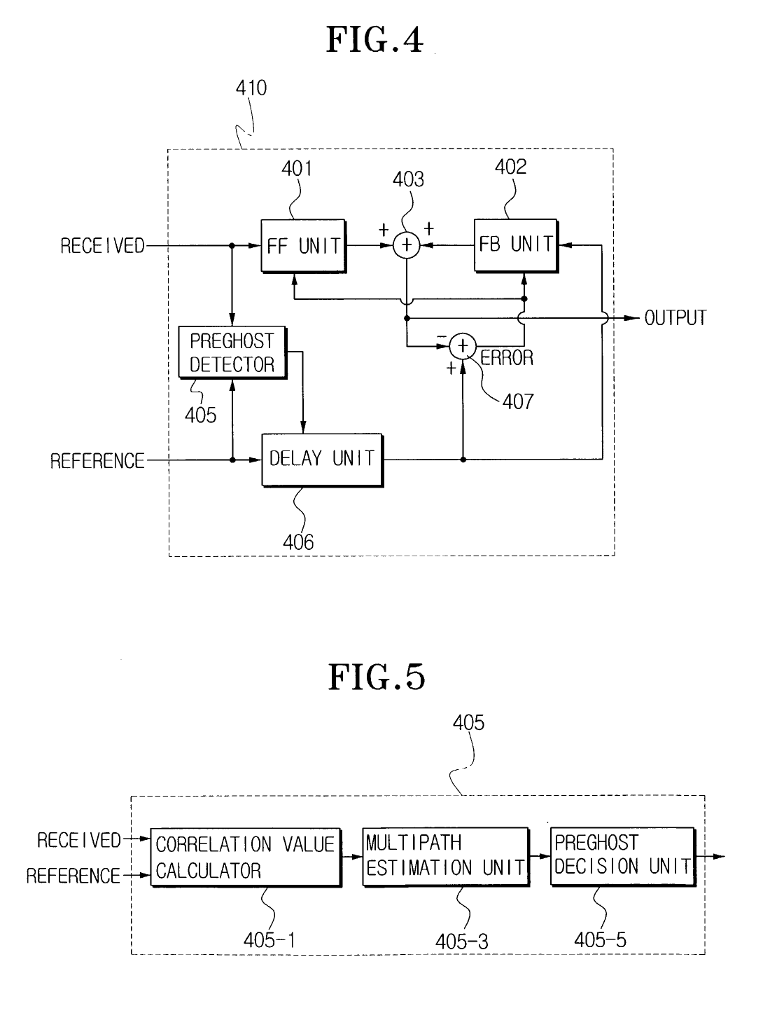

FIG. 4 is a block diagram of a DFE (Decision Feedback Equalizer), in accordance with an aspect of the present invention.

The DFE 410 includes an FF (Feed Forward) unit 401, an FB (Feed Back) unit 402, a first adder 403, a pre-ghost detector 405, a delay unit 406, and a second adder 407.

The FF unit 401, which is an FIR type filter, filters pre-ghosts received before a main-ghost, which is a signal having a highest level among multipath signals.

The FB unit 402, which is an IIR type filter, filters post-ghosts received after the main-ghost.

The first adder 403 adds output signals from the FF unit 401 and FB unit 402, and a resulting signal is outputted from the DFE 410.

The pre-ghost detector 405 detects one ghost from ghosts having levels higher than a predetermined threshold out of the pre-ghosts received before the main-ghost, and then detects a time delay of the detected ghost.

The delay unit 406 delays the field synchronization signal for the detected time delay of the detected ghost, thereby outputting the field synchronization signal to the FB unit 402.

The second adder 407 calculates an equalization error by adding the resulting signal from the first adder 403 through the FF and FB units 401 and 402 and the field synchronization signal delayed for the time delay time of the detected ghost by the delay unit 406.

By using the equalization error, coefficients of the FF unit 401 and the FB unit 402 are updated to filter the multipath.

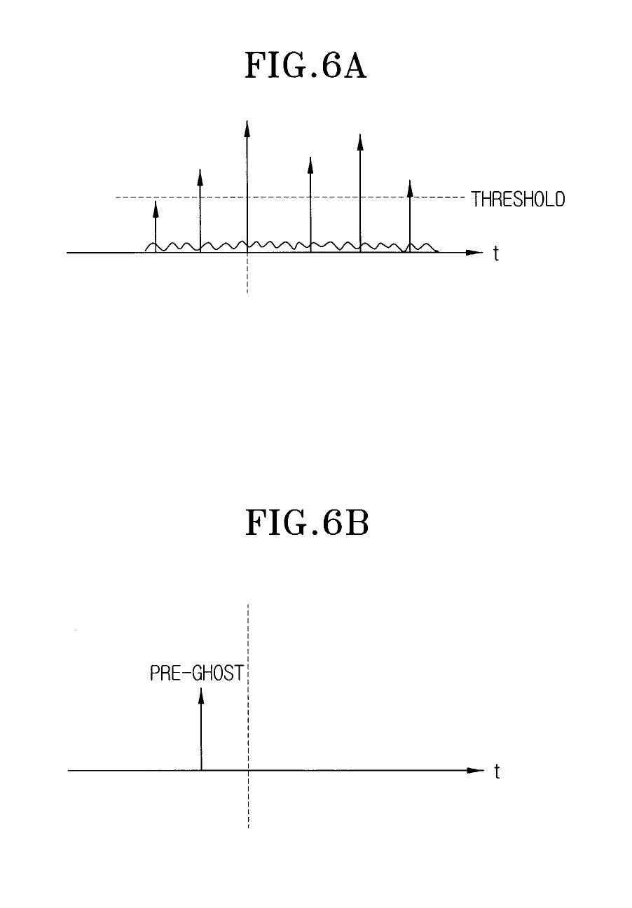

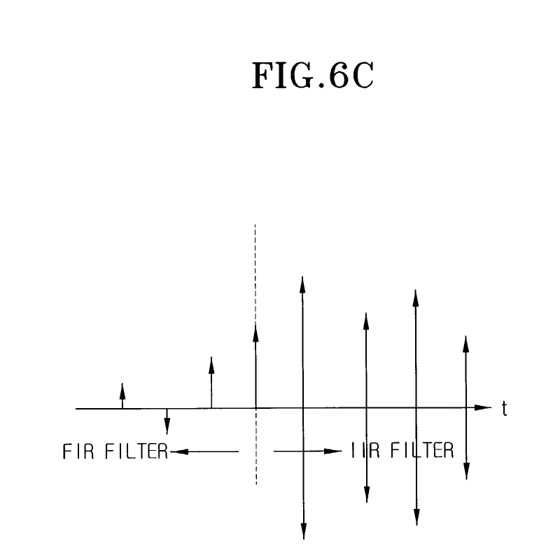

FIG. 5 is a detailed block diagram of the pre-ghost detector 405 of FIG. 4. A process to detect a particular ghost out of the ghosts received before a ghost having a highest level will hereinafter be described with reference to FIGS. 6A to 6C.

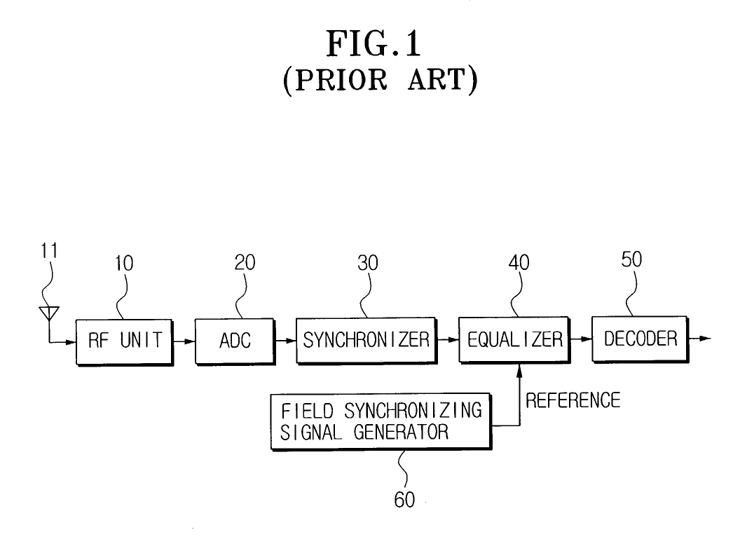

The pre-ghost detector 405 includes a correlation value calculator 405-1, a multipath estimation unit 405-3 and a pre-ghost decision unit 405-5. The correlation calculator 405-1 calculates a correlation value using a correlation between the pre-ghost received before the main-ghost and the field synchronization signal, a reference signal, from a field synchronization signal generator 60 (see FIG. 1) installed in the receiver. Accordingly, the multipath estimation unit 405-3 estimates a delay profile of the pre-ghost received as shown in FIG. 6A.

The pre-ghost decision unit 405-5 detects one ghost from the ghosts having levels higher than the predetermined threshold out of the pre-ghosts received prior to the ghost having the highest level based on the estimated multipath delay profile by applying a conventional adaptive threshold algorithm or a conventional fixed threshold algorithm, and then, detects the time delay of the detected ghost.

Namely, the ghost detected by the pre-ghost decision unit 405-5 may be a ghost received at first or the ghost having the highest level from the ghosts having higher levels than the predetermined threshold. The pre-ghost decision unit 405-5 then detects the time delay of the detected ghost in accordance with one of the following procedures.

The pre-ghost detector 405 provides the delay unit 406 with the detected time delay, then the delay unit 406 delays an input field synchronization signal from the field synchronization generator 60 (see FIG. 1) for the time delay.

In short, the ghosts of the pre-ghost received are filtered with reference to the ghost detected by the pre-ghost detection unit 405, from the ghosts received before the ghost having the highest level by synchronizing the field synchronization signal from the field synchronization generator 60 with the detected ghost.

FIG. 6C illustrates an operation of the ghost received at first from the ghosts having the levels higher than the predetermined threshold, which are received before the main-ghost. The ghost received at first is detected as the main signal.

It can be noticed that a number and levels of ghosts received before the main ghost are relatively reduced when a specific ghost is detected as the main signal by the pre-ghost detector 405 as shown in FIG. 6C, as compared to when the ghost having the highest level is detected as the main signal from multipath signals as shown in FIG. 6A, which can reduce an occurrence of the equalization error. The equalization error may be caused by operation features of the FIR type filter, which gradually reduces levels of the ghosts received before the main signal to filter the ghosts, and also reduces a number of taps of the filter needed.

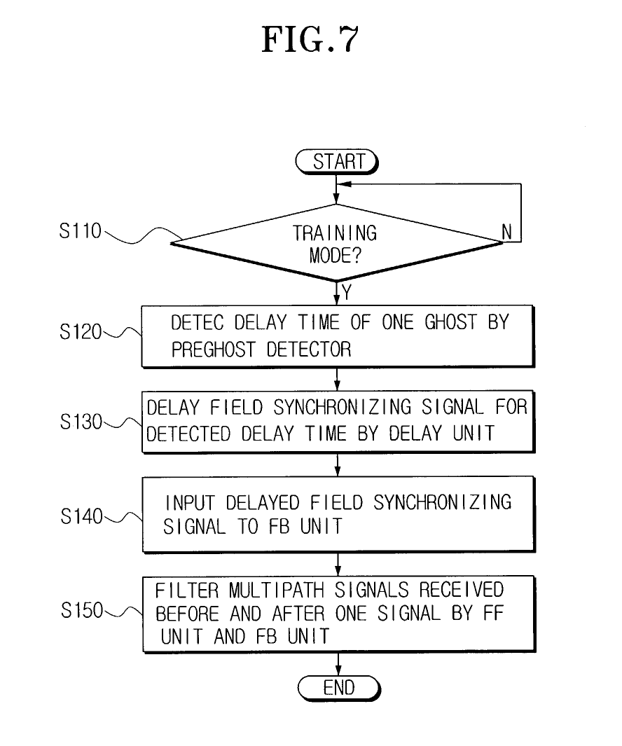

FIG. 7 is a flow chart illustrating an equalizing method of the decision feedback equalizer in FIG. 4. The equalizing method, in accordance with an aspect of the present invention, will be described hereinafter.

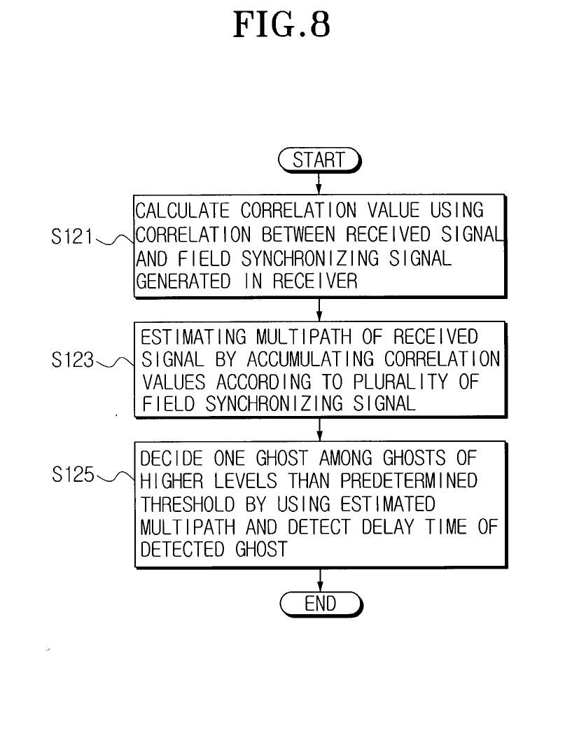

At S100, when the DFE 410 operates in a training mode, the pre-ghost detector 405 detects one ghost from the ghosts having the higher levels than the predetermined threshold by applying the predetermined threshold to the pre-ghosts received before the ghost having the highest level. At S120, the DFE 410 detects a delay time of the detected ghost. Hereinafter, a method to detect the time delay of the detected ghost at S120 will be described with reference to FIG. 8.

At S121, a correlation value is calculated using a correlation between the pre-ghost received and the input field synchronization signal from the field synchronization generator 60 (see FIG. 1). A plurality of field synchronization signals is used to calculate correlation values to be cumulated, thereby estimating the multipath of the pre-ghost received. At S125, the one ghost from the ghosts having the higher levels than the predetermined threshold is detected by applying the predetermined threshold to the pre-ghosts received before the ghost having the highest level, using the conventional adaptive threshold algorithm or the conventional fixed threshold algorithm, and then, the time delay of the ghost is detected.

Namely, the ghost detected by the pre-ghost decision unit 405-5 may be the ghost received at the first or the ghost of the highest level from the ghosts of the higher levels than the predetermined threshold. The pre-ghost decision unit 405-5 then detects the delay time of the detected ghost in accordance with one of the following ways.

At S130, the pre-ghost detector 405 provides the delay unit 406 with the detected delay time, then the delay unit 406 delays the input field synchronization signal for the detected delay time. At S140, the delayed field synchronization signal is then input to the FB unit 402.

The equalization process continues as follows.

The delayed field synchronization signal and the pre-ghost received are input to the FF unit 401 and FB unit 402, respectively, for filtering, and are output to the first adder 403. The first adder 403 adds output signals from the FF unit 401 and FB unit 402. The second adder 407 calculates the equalization error using the output signal from the first adder 403 and the field synchronization signal delayed for the predetermined time at the delay unit 406. The equalization error calculated by the second adder 407 is input to the FF unit 401 and the FB unit 402, where the coefficients of the FIR and IIR filters are respectively updated in accordance with the input equalization error.

In turn, at S150, the multipath is gradually filtered by updating the coefficients of the FIR and IIR filters of the FF unit 401 and FB unit 402, respectively. The pre-ghost detector 405 uses a signal received at first or a signal of highest level among the ghosts of the higher level, than the predetermined threshold as the main signal to filter the ghosts.

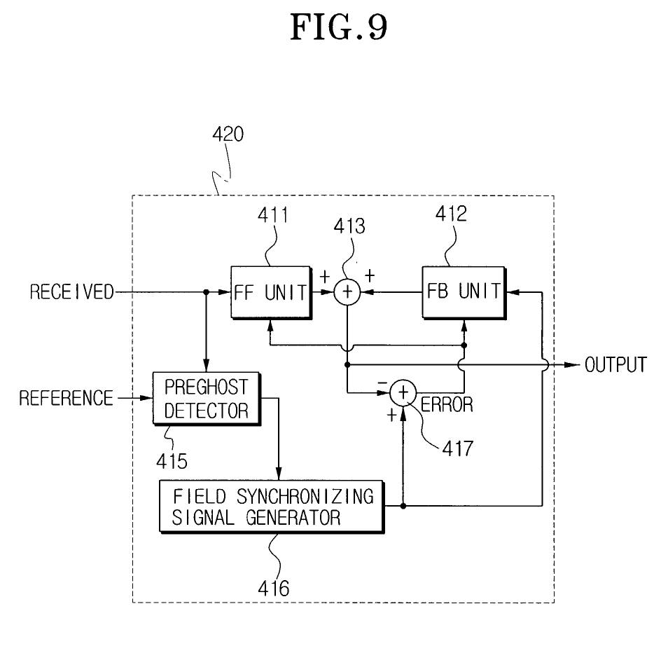

FIG. 9 is a block diagram of a DFE 420, in accordance with another aspect of the present invention.

The DFE 420 includes an FF unit 411, an FB unit 412, a first adder 413, a pre-ghost detector 415, a field synchronization signal generator 416, and a second adder 417.

The FF unit 411, which is an FIR type filter, filters pre-ghosts received before the main-ghost, which is a signal of highest level among multipath signals.

The FB unit 412, which is an IIR type filter, filters post-ghosts received after the main-ghost.

The first adder 413 adds output signals from the FF unit 411 and FB unit 412, and the resulting signal is output from the DFE 420.

The pre-ghost detector 405 detects one ghost from the ghosts having levels higher than the predetermined threshold out of the pre-ghosts received before the main-ghost, and then, detects the time delay of the detected ghost. The pre-ghost detector 415 has the same construction and operation as the pre-ghost detector 405 in FIG. 5.

The pre-ghost detector 415 estimates a delay profile of the pre-ghost received through the correlation value calculator 405-1 and the multipath estimation unit 405-3 by using the pre-ghost received and a second field synchronization signal input from a field synchronization signal generator 60 (see FIG. 1) installed in the receiver. A pre-ghost decision unit 405-5 of the pre-ghost detector 415 detects one ghost from the ghosts having higher levels than the predetermined threshold by applying the predetermined threshold to pre-ghosts received before the ghost having the highest level based on the estimated multipath and detects the time delay of the detected ghost.

Namely, the ghost detected by the pre-ghost decision unit 405-5 may be a ghost received at first or the ghost having the highest level from the ghosts having the higher levels than the predetermined threshold.

The field synchronization signal generator 416 generates the first field synchronization signal delayed for the time delay of the signal detected by the pre-ghost detector 415. The first field synchronization signal from the field synchronization signal generator 416 is input to the FB unit 412.

The second adder 417 calculates the equalization error by adding the output signal from the first adder 413, which is an added signal from signals from the FF unit 411 and FB unit 412, and the first field synchronization signal from the field synchronization signal generator 416.

By using this equalization error, coefficients of the FF unit 411 and the FB unit 412 are updated to filter the multipath.

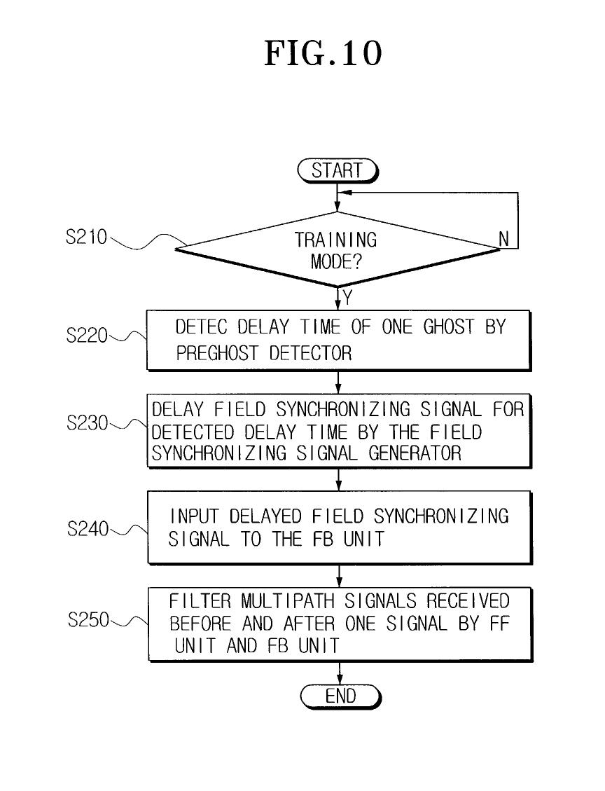

FIG. 10 is a block diagram of a decision feedback equalizer, in accordance with another aspect of the present invention. Hereinafter, an equalization method will be described with respect to FIG. 10.

At S210, when the DFE 420 operates in the training mode at S220, the pre-ghost detector 415 detects the time delay of one ghost from the ghosts received before the ghost having the highest level. Here, the process to detect the time delay of the one ghost at S120 is the same as the process shown in FIG. 8.

At S121, a correlation value is calculated by using a correlation between the pre-ghost received and the second field synchronization signal from the field synchronization generator 60 (see FIG. 1) installed at the receiver. At S123, a plurality of field synchronization signals is used to calculate correlation values to be cumulated, thereby estimating the multipath of the pre-ghost received. At S125, one ghost from the ghosts having the higher levels than the predetermined threshold is detected by applying the predetermined threshold to pre-ghosts received before the ghost having the highest level, using the conventional adaptive threshold algorithm or the fixed threshold algorithm, and then the time delay of the detected ghost is detected.

Namely, the ghost detected by the pre-ghost detected unit 405-5 may be the ghost received at first or the ghost having the highest level from the ghosts having the higher levels than the predetermined threshold. The pre-ghost decision unit 405-5, then, detects the delay time of the detected ghost in accordance with one the following ways.

Next, at S230, the detected delay time is provided to the field synchronization signal generator 416 to generate the first field synchronization signal delayed for the detected time delay. At S240, the first field synchronization signal is then input to the FB unit 412.

A successive equalization process will be omitted here, because it is the same as the above described equalization process, in accordance with an aspect of the present invention.

The following Table 1 shows error rates of equalization results with respect to delay times and levels of ghosts. The error rates shown in FIG. 1 relate to the results of equalizing ghosts received before a main signal, wherein the main signal is detected as a signal of 0 dB and 0 μs time delay. Each of the error rates in parentheses relates to the result of equalizing each ghost, wherein the main signal is detected as each ghost.

| Delayed | Amplitude | | | | | | | | | | | |
|---|---|---|---|---|---|---|---|---|---|---|---|---|
| time | −5 dB | | −4 dB | | −3 dB | | −2 dB | | −1 dB | | 0 dB | |
| −1 μs | 0 | (0) | 0 | (0) | 0 | (0) | 0 | (0) | 2.3E−4 | (0) | 0.7490 | (0) |
| −2 μs | 0 | (0) | 0 | (0) | 0 | (0) | 0.0028 | (0) | 0.4706 | (1E−4) | 0.8031 | (0) |
| −3 μs | 0 | (0) | 0 | (0) | 8.3E−4 | (0.0079) | 0.2577 | (0.0306) | 0.6642 | (0) | 0.8353 | (0) |
| −4 μs | 0 | (0.0001) | 6.7E−5 | (0.0306) | 0.1183 | (0.1095) | 0.5 | (0.0076) | 0.7459 | (0) | 0.08537 | (0) |
| −5 μs | 0.0025 | (0.2006) | 0.1226 | (0.2469) | 0.4154 | (0.0607) | 0.6683 | (0) | 0.7959 | (0) | 08663 | (0) |
| −6 μs | 0.0018 | (0.1946) | 0.1123 | (0.2349) | 0.4071 | (0.0482) | 0.6505 | (0) | 0.7918 | (0) | 0.8603 | (0) |
| −7 μs | 0.3124 | (0.3389) | 0.5178 | (0.0663) | 0.6714 | (0) | 0.7763 | (0) | 0.8395 | (0) | 0.8813 | (0) |
| −8 μs | 0.3505 | (0.3557) | 0.5438 | (0.0061) | 0.6909 | (0) | 0.7902 | (0) | 0.8499 | (0) | 0.8871 | (0) |
| −9 μs | 0.3468 | (0.3474) | 0.5440 | (0.0078) | 0.6911 | (0) | 0.7861 | (0) | 0.8487 | (0) | 0.8885 | (0) |
| −10 μs | 0.3347 | (0.3271) | 0.5324 | (0.0047) | 0.6828 | (0) | 0.7813 | (0) | 0.8433 | (0) | 0.88209 | (0) |

For example, an error rate is ‘0.6642’ when a ghost of −1 dB and −3 μs delay time delay time is equalized as a pre-ghost, and is ‘0’ when the ghost is equalized by deciding it as a main ghost.

As shown in Table 1, a quality of equalization is improved when levels of ghosts are higher than a threshold −1 dB. That is, the quality of equalization is not improved when the main ghost is detected as the ghost having a level too low, but it is remarkably improved when the main ghost is detected as the pre-ghost having the level higher than the predetermined threshold.

Therefore, the quality of equalization can be improved by removing multipaths with reference to a certain ghost detected by applying the predetermined threshold to ghosts received before the ghost having the highest level.

According to an aspect of the present invention, ghosts are filtered with reference to a main ghost, which is detected as one ghost from ghosts having levels higher than a predetermined threshold by applying the predetermine threshold to ghosts received before the ghost having the highest level from a received multipath signal to improve a quality of equalization.

While the invention has been shown and described with reference to certain preferred embodiments thereof, it will be understood by those skilled in the art that various changes in form and details may be made therein without departing from the spirit and scope of the invention as defined by the appended claims.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, and all such modifications and equivalents would fall within the scope of the invention.

What is claimed is:

1. An equalizer of a single carrier receiver, comprising:
a pre-ghost detection unit detecting one ghost from ghosts having levels higher than a predetermined threshold and detecting a time delay of the detected ghost with respect to a main ghost;
a delay unit delaying an input field synchronization signal for the time delay and outputting a delay signal indicative thereof;
an FF unit receiving a pre-ghost to filter the ghosts received before the detected ghost; and
an FB unit receiving the delayed field synchronization signal to filter the ghosts received after the detected ghost.

2. The equalizer according to claim 1, further comprising:
a first adding unit adding output signals from the FF unit and the FB unit and outputting an output signal indicative thereof; and
a second adding unit calculating an equalization error by using the output signal from the first adding unit and the delay signal or the delayed field synchronization signal from the delay unit, wherein the FF unit and FB unit filter the ghosts received before and after the detected ghost, respectively, according to the equalization error.

3. The equalizer according to claim 1, wherein the FF unit comprises an FIR type first filter and the FB unit includes an IIR type second filter, wherein the FF unit and FB unit update coefficients of the first and second filters, respectively, according to the equalization error.

4. The equalizer according to claim 1, wherein the pre-ghost detection unit comprises:
a correlation value calculation unit calculating a correlation value between the pre-ghost received and the field synchronization signal;
a multipath estimation unit cumulating correlation values calculated using a plurality of field synchronization signals to estimate a multipath of the pre-ghost received; and
a pre-ghost decision unit detecting the ghost from the ghosts having the levels higher than the predetermined threshold and detecting the time delay of the detected ghost.

5. The equalizer according to claim 4, wherein the pre-ghost decision unit detects one ghost received at first from the ghosts having the higher levels than the predetermined threshold as a main signal to detect the time delay of the detected ghost.

6. An equalization method of a single carrier receiver, comprising:
detecting one ghost from ghosts having levels higher than a predetermined threshold as a pre-ghost and detecting a time delay of the detected pre-ghost with respect to a main ghost;
delaying an input field synchronization signal for the time delay; and
filtering the ghosts received before and after the detected ghost.

7. The equalization method according to claim 6, further comprising:
calculating an equalization error using the delayed field synchronization signal, wherein the filtering of the ghosts filters the ghosts received before and after the detected ghost according to the equalization error.

8. The equalization method according to claim 6, wherein the filtering of the ghosts filters using an FIR type first filter and an IIR type second filter, the ghosts received before and after the detected ghost by updating coefficients of the first and second filters, respectively, according to the equalization error.

9. The equalization method according to claim 6, wherein the detecting of the pre-ghost comprises:
calculating a correlation value between the pre-ghost received indicative of the ghosts received before the detected ghost and the field synchronization signal;
estimating a multipath of the pre-ghost received by cumulating correlation values calculated using a plurality of field synchronization signals; and
detecting the ghost from the ghosts having the levels higher than the predetermined threshold and detecting the time delay of the detected ghost.

10. The equalization method according to claim 9, wherein the detecting of the ghost detects a ghost received at first from the ghosts having higher levels than the predetermined threshold to detect the time delay of the detected ghost.

11. An equalizer for a single carrier receiver, comprising:
a pre-ghost detection unit detecting one ghost from ghosts having levels higher than a predetermined threshold and detecting a time delay of the detected ghost with respect to a main ghost;
a field synchronization signal generation unit generating a first field synchronization signal delayed for the time delay;
an FF unit receiving a pre-ghost to filter the ghosts received before the detected ghost; and
an FB unit receiving the delayed first field synchronization signal to filter the ghosts received after the detected ghost.

12. The equalizer according to claim 11, further comprising:
a first adding unit adding output signals from the FF unit and the FB unit and outputting an output signal indicative thereof; and
a second adding unit calculating an equalization error by using the output signal from the first adding unit and the delayed first field synchronization signal from the field synchronization signal generation unit, wherein the FF unit and FB unit filter the ghosts received before and after the detected ghost, respectively, according to the equalization error.

13. The equalizer according to claim 11, wherein the FF unit comprises an FIR type first filter and the FB unit includes an IIR type second filter, wherein the FF unit and FB unit update coefficients of the first and second filters, respectively, according to the equalization error.

14. The equalizer according to claim 11, wherein the pre-ghost detection unit includes:
a correlation value calculation unit calculating a correlation value between the pre-ghost received and an input second field synchronization signal;
a multipath estimation unit cumulating correlation values calculated using a plurality of second field synchronization signals to estimate a multipath of the pre-ghost received; and
a pre-ghost decision unit detecting the ghost from the ghosts having levels higher than the predetermined threshold and detecting the time delay of the detected ghost.

15. The equalizer according to claim 14, wherein the pre-ghost decision unit detects one ghost received at first from the ghosts having the higher levels than the predetermined threshold as the main signal to detect the time delay of the detected ghost.

16. An equalization method of a single carrier receiver, comprising:
detecting one ghost from ghosts having levels higher than a predetermined threshold as a pre-ghost and detecting a time delay of the detected pre-ghost with respect to a main ghost;
generating a first field synchronization signal delayed for the time delay; and
filtering the ghosts received before and after the detected ghost.

17. The equalization method according to claim 16, further comprising:
calculating an equalization error using the delayed first field synchronization signal, wherein the filtering of the ghosts filters the ghosts received before and after the detected ghost according to the equalization error.

18. The equalization method according to claim 16, wherein the filtering of the ghosts filters using an FIR type first filter and an IIR type second filter, the ghosts received before and after the detected ghost by updating coefficients of the first and second filters, respectively, according to the equalization error.

19. The equalization method according to claim 16, wherein the detecting of the pre-ghost comprises:
calculating a correlation value between a pre-ghost received indicative of the ghosts received before the detected ghost and an input second field synchronization signal;
estimating a multipath of the pre-ghost received by cumulating correlation values calculated using a plurality of input second field synchronization signals; and
detecting the ghost from the ghosts having the levels higher than the predetermined threshold and detecting the time delay of the detected ghost.

20. The equalization method according to claim 19, wherein the detection of the ghost detects a ghost received at first from the ghosts having the higher levels than the predetermined threshold to detect the time delay of the detected ghost.

21. An equalizer of a single carrier receiver, comprising:
an FF (Feed Forward) unit filtering pre-ghosts received before a main-ghost;
an FB (Feed Back) unit filtering post-ghosts received after the main-ghost;
a first adder adding the filtered pre-ghosts and post-ghosts and outputting a resulting signal indicative thereof;
a pre-ghost detector detecting one ghost from ghosts having levels higher than a predetermined threshold from the pre-ghosts received before the main-ghost, and detecting a time delay of the detected ghost;
a delay unit delaying a field synchronization signal for the detected time delay and outputting the field synchronization signal to the FB unit; and
a second adder calculating an equalization error by adding the resulting signal from the first adder and the delayed field synchronization signal, and using the equalization error to update coefficients of the FF unit and the FB unit.

22. The equalizer according to claim 21, wherein the main ghost is a signal having a highest level among multipath signals.

23. The equalizer according to claim 21, wherein the FF unit is an FIR type filter and the FB unit is an IIR type filter.

24. The equalizer according to claim 21, wherein the pre-ghost detector comprises:
a correlation value calculator calculating a correlation value using a correlation between the pre-ghost received before the main-ghost and the field synchronization signal,
a multipath estimation unit estimating a delay profile of the pre-ghost received, and
a pre-ghost decision unit detecting one ghost from the ghosts having levels higher than the predetermined threshold out of the pre-ghosts received prior to the ghost having the highest level, based on the estimated delay profile, and detecting the time delay of the detected ghost.

25. The equalizer according to claim 24, wherein the ghost detected by the pre-ghost decision unit is a ghost received at first or the ghost having the highest level from the ghosts having higher levels than the predetermined threshold.

26. The equalizer according to claim 21, wherein the ghosts of the received signal are filtered with reference to the ghost detected by the pre-ghost decision unit, from the ghosts received before the ghost having the highest level, by synchronizing the field synchronization signal from the field synchronization generator with the detected ghost.

27. An equalization method of a single carrier receiver, comprising:
filtering pre-ghosts received before a main-ghost;
filtering post-ghosts received after the main-ghost;
adding the filtered pre-ghosts and post-ghosts and outputting a resulting signal indicative thereof;
detecting one ghost from ghosts having levels higher than a predetermined threshold from the pre-ghosts received before the main-ghost;
detecting a time delay of the detected ghost;
delaying a field synchronization signal for the detected time delay of the detected ghost; and
calculating an equalization error by adding the resulting signal and the delayed field synchronization signal.

28. An equalization method of a single carrier receiver, comprising:
detecting one ghost from ghosts having higher levels than a predetermined threshold by applying the predetermined threshold to a pre-ghost received before the ghost having the highest level;
detecting a time delay of the detected ghost;
delaying an input field synchronization signal for the time delay; and
filtering the ghosts received before and after the detected ghost.

29. The equalization method of claim 28, further comprising:
calculating a correlation value using a correlation between the pre-ghost received and the input field synchronization signal.

30. The equalization method of claim 28, wherein a plurality of field synchronization signals is used to calculate correlation values to be cumulated to estimate a multipath of the pre-ghost received.
